(19) United States
(12) Patent Application Publication
(10) Pub. No.: US 2010/0135088 A1
(43) Pub. Date: Jun. 3, 2010

(54) Operation method of semiconductor device

(75) Inventors: Won-joo Kim, Hwaseong-si (KR); Sang-moo Choi, Yongin-si (KR); Tae-hee Lee, Yongin-si (KR)

Correspondence Address: HARNESS, DICKEY & PIERCE, P.L.C., P.O. BOX 8910, RESTON, VA, 20195, US

(73) Assignee: Samsung Electronics Co., Ltd.

(21) Appl. No.: 12/591,199

(22) Filed: Nov. 12, 2009

(30) Foreign Application Priority Data
Dec. 1, 2008 (KR) 10-2008-0120684

(51) Int. Cl. G11C 7/00; G11C 5/14

(52) U.S. Cl. 365/189.16; 365/226; 365/218

(57) ABSTRACT

Provided is a method of operating a semiconductor device, in which timing for switching each of a drain voltage pulse signal and a gate voltage pulse signal from a first state to a second state is controlled in an erase mode and a write mode.

### PRIORITY STATEMENT

This application claims priority under 35 U.S.C. §119 to Korean Patent Application No. 10-2008-0120684, filed on Dec. 1, 2008, in the Korean Intellectual Property Office (KIPO), the entire contents of which is incorporated herein in by reference.

### BACKGROUND

### Field

Example embodiments relate to a method of operating a semiconductor device, and more particularly, to a method of operating a semiconductor device, in which timing for switching each of a drain voltage pulse signal and a gate voltage pulse signal from a first state to a second state is controlled.

A conventional memory, for example, a DRAM, may include one transistor and one capacitor as a memory cell. However, there are limitations to the scalability of the conventional memory, due to the capacitor, in particular, the size of the capacitor. As a result, a memory including one transistor (1T) and no capacitor as a memory cell, referred to as “a capacitor-less memory or 1-T DRAM”, has been studied. The 1-T DRAM may be not only simple to manufacture but also easy to make a memory device with larger density.

### SUMMARY

Example embodiments provide a method of operating a semiconductor device, in which timing for switching each of a drain voltage pulse signal and a gate voltage pulse signal from a first state to a second state is controlled in an erase mode and a write mode.

According to the example embodiments, there is provided a method of operating at least one semiconductor device including a drain region, a source region, a floating body region, and a gate region, wherein, in an erase mode, a gate voltage pulse signal supplied to the gate region is switched from an enabled state to a standby state after a drain voltage pulse signal supplied to the drain region is switched from an enabled state to a standby state, where a data state of the semiconductor device is changed to a first state in the erase mode; in a write mode, the drain voltage pulse signal is switched from the enabled state to the standby state after the gate voltage pulse signal is switched from the enabled state to the standby state, where the data state of the semiconductor device is changed to a second state in the write mode; a standby voltage of the drain voltage pulse signal is higher than an enable voltage of the drain voltage pulse signal, and an enable voltage of the gate voltage pulse signal is higher than a standby voltage of the gate voltage pulse signal.

According to another aspect of the inventive concept, there is provided a method of erasing data from a plurality of semiconductor devices each including a drain region, a source region, a floating body region, and a gate region, wherein a drain voltage pulse signal supplied to the drain region is switched from a standby state to an enabled state before, after or at the same time that a gate voltage pulse signal supplied to the gate region is switched from a standby state to an enabled state, the gate voltage pulse signal is switched from the standby state to the enabled state after the drain voltage pulse signal is switched from the standby state to the enabled state, or the gate voltage pulse signal is switched from the standby state to the enabled state at the same time that the drain voltage pulse signal is switched from the standby state to the enabled state, and a standby voltage of the drain voltage pulse signal is higher than an enable voltage of the drain voltage pulse signal, and an enable voltage of the gate voltage pulse signal is higher than a standby voltage of the gate voltage pulse signal.

According to another aspect of the inventive concept, there is provided a method of writing data to a plurality of semiconductor devices each including a drain region, a source region, a floating body region, and a gate region, wherein a drain voltage pulse signal supplied to the drain region is switched from a standby state to an enabled state before, after or at the same time that a gate voltage pulse signal supplied to the gate region is switched from a standby state to an enabled state, the drain voltage pulse signal is switched from the enabled state to the standby state after the gate voltage pulse signal is switched from the enabled state to the standby state, or the gate voltage pulse signal is switched from the enabled state to the standby state at the same time that the drain voltage pulse signal is switched from the enabled state to the standby state, and a standby voltage of the drain voltage pulse signal is higher than an enable voltage of the drain voltage pulse signal, and an enable voltage of the gate voltage pulse signal is higher than a standby voltage of the gate voltage pulse signal.

### BRIEF DESCRIPTION OF THE DRAWINGS

Example embodiments will be more clearly understood from the following brief description taken in conjunction with the accompanying drawings. FIGS. 1-16 represent non-limiting, example embodiments as described herein.

FIG. 1 is a cross-sectional view of an example of a 1-transistor (T) dynamic random access memory (DRAM) that operates according to an embodiment of a method of operating a semiconductor device;

FIG. 2 illustrates a state in which a plurality of carriers are generated in the 1-T DRAM of FIG. 1 in a write mode;

FIG. 3 illustrates a state in which the carriers are stored after the write mode of FIG. 2 is performed;

FIG. 4 illustrates a state in which the carriers are not removed from the 1-T DRAM of FIG. 1 in an erase mode;

FIG. 5 illustrates voltage pulse signals supplied in operation modes in an example embodiment of a method of operating a semiconductor device;

FIG. 6 illustrates voltage pulse signals supplied in operation modes in an example embodiment of a method of operating a semiconductor device;

FIG. 7 is a graph illustrating the amount of current that flows through a semiconductor device when the voltage pulse signals are supplied in the operation modes of FIG. 6;

FIG. 8 is a circuit diagram of a semiconductor device that operates according to an example embodiment of a method of operating a semiconductor device;

FIGS. 9A and 9B illustrate voltage pulse signals that may be supplied to the semiconductor device of FIG. 8 in an erase mode;

FIGS. 10A and 10B illustrate voltage pulse signals that may be supplied to the semiconductor device of FIG. 8 in a write mode;

FIGS. 11 to 14 illustrate various voltage pulse signals supplied in operation modes in an example embodiment of a method of operating a semiconductor device;

FIG. 15 is a cross-sectional view of another example of a 1-T DRAM that operates according to an example embodiment of a method of operating a semiconductor device; and

FIG. 16 is a cross-sectional view of another example a 1-T DRAM that operates according to an example embodiment of a method of operating a semiconductor device.

It should be noted that these Figures are intended to illustrate the general characteristics of methods, structure and/or materials utilized in certain example embodiments and to supplement the written description provided below. These drawings are not, however, to scale and may not precisely reflect the precise structural or performance characteristics of any given embodiment, and should not be interpreted as defining or limiting the range of values or properties encompassed by example embodiments. For example, the relative thicknesses and positioning of molecules, layers, regions and/or structural elements may be reduced or exaggerated for clarity. The use of similar or identical reference numbers in the various drawings is intended to indicate the presence of a similar or identical element or feature.

### DETAILED DESCRIPTION OF EXAMPLE EMBODIMENTS

Example embodiments will now be described more fully with reference to the accompanying drawings, in which example embodiments are shown. Example embodiments may, however, be embodied in many different forms and should not be construed as being limited to the embodiments set forth herein; rather, these embodiments are provided so that this disclosure will be thorough and complete, and will fully convey the concept of example embodiments to those of ordinary skill in the art. In the drawings, the thicknesses of layers and regions are exaggerated for clarity. Like reference numerals in the drawings denote like elements, and thus their description will be omitted.

It will be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present. Like numbers indicate like elements throughout. As used herein the term “and/or” includes any and all combinations of one or more of the associated listed items.

It will be understood that, although the terms “first”, “second”, etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, a first element, component, region, layer or section discussed below could be termed a second element, component, region, layer or section without departing from the teachings of example embodiments.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

The terminology used herein is for the purpose of describing particular embodiments only and is not intended to be limiting of example embodiments. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Example embodiments are described herein with reference to cross-sectional illustrations that are schematic illustrations of idealized embodiments (and intermediate structures) of example embodiments. As such, variations from the shapes of the illustrations as a result, for example, of manufacturing techniques and/or tolerances, are to be expected. Thus, example embodiments should not be construed as limited to the particular shapes of regions illustrated herein but are to include deviations in shapes that result, for example, from manufacturing. For example, an implanted region illustrated as a rectangle may have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of example embodiments.

Unless otherwise defined, all terms (including technical and scientific terms) used herein have the same meaning as commonly understood by one of ordinary skill in the art to which example embodiments belong. It will be further understood that terms, such as those defined in commonly-used dictionaries, should be interpreted as having a meaning that is consistent with their meaning in the context of the relevant art and will not be interpreted in an idealized or overly formal sense unless expressly so defined herein.

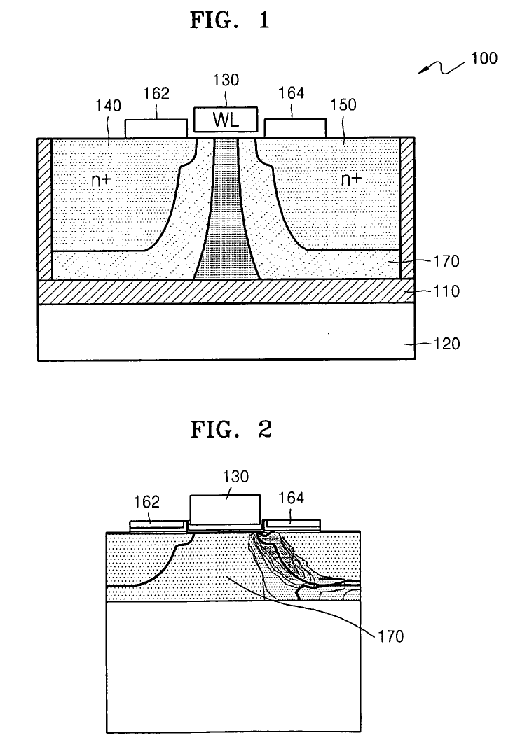

FIG. 1 is a cross-sectional diagram of an example memory cell of 1-transistor dynamic random access memory (1T-DRAM) device according to example embodiments. Referring to FIG. 1, a memory cell 100 of 1T-DRAM may include an insulating layer 110 on a semiconductor substrate 120, a body region 170, a gate electrode 130, a source electrode 162, a drain electrode 164, a source region 140, and a drain region 150. The source region 140 and the drain region 150 may be doped with impurities. According to example embodiments, the source region 140 and the drain region 150 may be interchanged with each other, and therefore the source electrode 162 and the drain electrode 164 may be interchanged with each other. For example, the semiconductor device of FIG. 1 may be bi-directional. A gate voltage, a drain voltage, and a source voltage, which are applied to the gate electrode 130, the source electrode 162, and the drain electrode 164, respectively, may be adjusted so that data can be written, erased, and/or read in the memory cell 100 of 1T-DRAM device

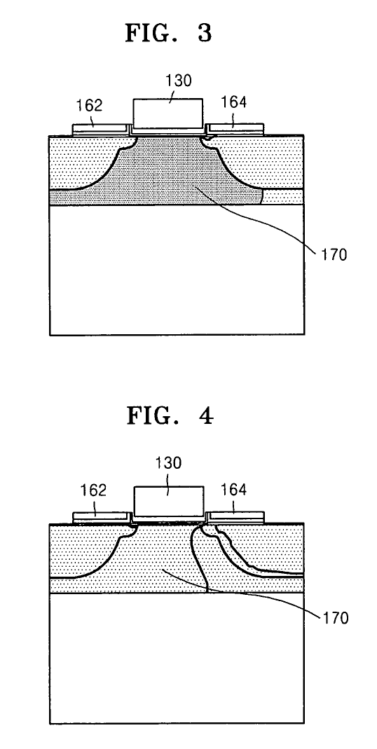

FIG. 2 is a cross-sectional diagram of write mode carrier generation in the memory cell of the 1T-DRAM device of FIG. 1, according to example embodiments. FIG. 3 is a cross-sectional diagram of carrier storage in the memory cell of FIG. 1 after the write operation of FIG. 2, according to example embodiments. FIG. 4 is a cross-sectional diagram illustrating erase mode carrier removal in the memory cell of FIG. 1, according to example embodiments.

In the write mode, a plurality of electron-hole pairs may be generated under given voltage bias condition by impact ionization or avalanche breakdown in a portion of the memory cell where the body region 170 and the drain region 150 contact each other, shown as highly darkened and darkened areas in FIG. 2. The generated electrons are moved into the drain region 150 and the generated holes, majority carries, are moved into the body region 170, shown as a darkened area in FIG. 3, under the given voltage bias condition. In contrast, if carriers are not generated in the write mode or are removed in an erase mode, no carriers are stored in the body region 170 as illustrated in FIG. 4.

If carriers are stored in the body region 170, this may be considered as data ‘1’ of the memory cell 100 of 1T-DRAM. On the other hand, when the body region 170 has no carriers stored, this may be considered as a data value of “0” of the memory cell 100 of 1T-DRAM. The carriers may be removed from the body region 170 (erase mode). After the erase mode, the body region 170 has a data state as illustrated in FIG. 4.

In the read mode, reading data from the memory cell of 1-T DRAM may by possible by measuring the amount of current that flows between the source region 140 and the drain region 150. If a large amount of carriers are stored in the body region 170, a large amount of current flows between the source region 140 and the drain region 150. If a small amount of carriers are stored in the body region 170, a small amount of current flows between the source region 140 and the drain region 150.

Performing the write mode of FIG. 2 or an erase/read mode of FIG. 4 may be possible by adjusting a gate voltage, a drain voltage and a source voltage that are applied to the gate electrode 130, the drain electrode 162 and the source electrode 164.

The source region 140 may be connected to a source line and the drain region 150 may be connected to a bit line. A source voltage may be applied to the source region 140 via the source line, and a drain voltage may be applied to the drain region 150 via the bit line. Also, the gate electrode 130 may be connected to a word line, and a gate voltage may be applied to the gate electrode 130 via the word line.

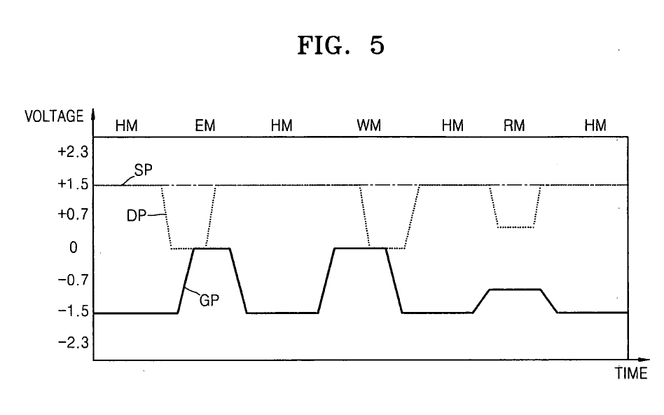

FIG. 5 illustrates voltage pulse signals supplied in operation modes in an example embodiment of a method of operating a semiconductor device. FIG. 5 illustrates an erase mode EM, a write mode WM, a read mode RM, and hold modes HM. Hereinafter, the enable voltage may be the enable-state voltage level and the standby voltage may be the standby-state voltage level. The enable state may be the state of a pulse which may be a positive pulse or a negative pulse. The standby state may be the state that is not a pulse state. The standby voltage may be the hold voltage.

In the erase mode EM, carriers are removed from a body region of the memory cell. When the drain voltage is the enable voltage, the current flows between the source region 140 and the drain region 150 due to the voltage difference between the source region 140 and the drain region 150, and carriers are generated in the body region 170. Then, when the drain voltage transition from an enable voltage to a standby voltage, the current does not flow between the source region 140 and the drain region 150 since the source voltage and the drain voltage are the same. However, since the gate voltage is still an enable voltage after the drain voltage transition from an enable voltage to a standby voltage, the gate voltage does not hold the carriers in the body region 170. Thus, the carriers are removed from the body region 170 when the gate voltage is an enable voltage and the drain voltage is a standby voltage. Then, when the gate voltage transition from an enable voltage to a standby voltage, the gate voltage maintains the state that the carriers are not stored in the body region 170. Referring to FIG. 5, in the erase mode EM, the drain voltage pulse signal DP is switched from an enable voltage to a standby voltage, and then the gate voltage pulse signal GP is switched from an enable voltage to a standby voltage.

In the write mode WM, carriers are generated and stored in the body region. When the drain voltage is the enable voltage, the current flows between the source region 140 and the drain region 150 due to the voltage difference between the source region 140 and the drain region 150, and carriers are generated in the body region 170. Then, when the gate voltage transition from an enable voltage to a standby voltage which is a negative voltage, i.e. −1.5V, the gate voltage holds the carriers generated in the body region 170. Thus, when the gate voltage is the standby voltage, the carriers are stored in the body region 170. Referring to FIG. 5, in the write mode WM, the gate voltage pulse signal GP is switched from the enable voltage to the standby voltage, and then the drain voltage pulse signal DP is switched from the enable voltage to the standby voltage.

In the read mode RM, the density (or the number) of the carriers stored in the body region is detected. When the drain voltage is the enable voltage, the current flows between the source region 140 and the drain region 150 due to the voltage difference between the source region 140 and the drain region 150. Thus, the amount of current flowing between the source region 140 and the drain region 150 may be measured and data may be read from the memory cell 100 of 1T-DRAM. The enable voltage of the gate voltage in the read mode may be less than the enable voltage of the gate voltage in the write mode so as not to change the data in the memory cell 100 of 1T-DRAM before and after the read mode. The hold mode HM is performed among the above operation modes.

Although FIG. 5 illustrates that an enable voltage of the drain voltage pulse signal DP and an enable voltage of the gate voltage pulse signal GP have 0 volts in the EM and the WM. A standby voltage of the drain voltage pulse signal DP and a standby voltage of the gate voltage pulse signal GP respectively have +1.5 volts and −1.5 volts. These pulse signals are not limited thereto.

Referring to FIG. 5, the enable voltage of a drain voltage pulse signal DP is lower than the standby voltage, and the enable voltage of a gate voltage pulse signal GP is higher than the standby voltage.

In the erase mode EM, the drain voltage pulse signal DP is switched from an enable voltage to a standby voltage, and then the gate voltage pulse signal GP is switched from an enable voltage to a standby voltage. In contrast, in the write mode WM, the gate voltage pulse signal GP is switched from the enable voltage to the standby voltage, and then the drain voltage pulse signal DP is switched from the enable voltage to the standby voltage.

In the erase mode EM, the drain voltage pulse signal DP is switched from the standby voltage to the enable voltage before the gate voltage pulse signal GP is switched from the standby voltage to the enable voltage. Also, in the write mode WM, the drain voltage pulse signal DP is switched from the standby voltage to the enable voltage after the gate voltage pulse signal GP is switched from the standby voltage to the enable voltage.

However, in the erase mode EM and the write mode WM, timing for switching the drain voltage pulse signal DP from the standby voltage to the enable voltage is not limited as compared to timing for switching the gate voltage pulse signal GP from the standby voltage to the enable voltage. For example, the drain voltage pulse signal DP may be switched from the standby voltage to the enable voltage before, after or at the same time that the gate voltage pulse signal GP is switched from the standby voltage to the enable voltage.

In the erase mode EM and the write mode WM, a source voltage signal SP supplied to a source region may have a constant voltage (see FIG. 5), and may be a source voltage pulse signal supplied in the form of a pulse.

Although FIG. 5 illustrates that the above voltage pulse signals are supplied in the order of the erase mode EM, the write mode WM, and the read mode RM, and a voltage pulse signal is supplied in the hold mode HM between these modes, the example embodiment is not limited thereto and the order of the erase mode EM, the write mode WM, the read mode RM, and the hold mode HM may be changed. Also, any of these modes may be skipped. For example, only the write mode WM or the erase mode EM may be performed from among these modes.

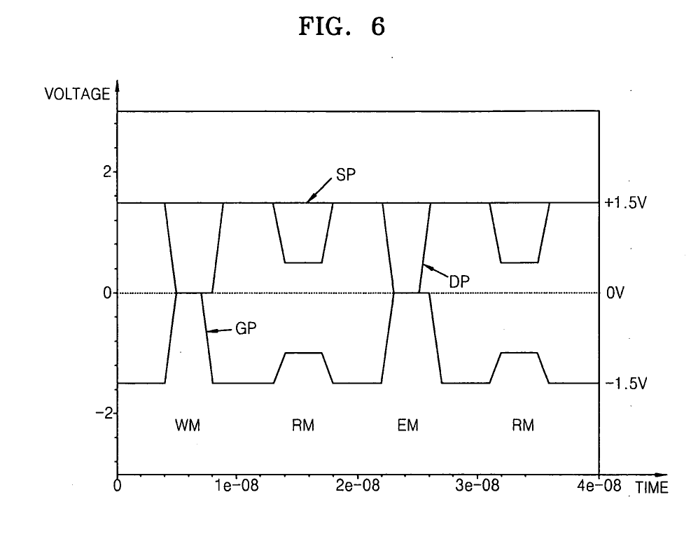

FIG. 6 illustrates voltage pulse signals supplied in operation modes in an example embodiment of a method of operating a semiconductor device. Similarly, referring to FIG. 6, in a write mode WM, a gate voltage pulse signal GP is switched from an enable voltage to a standby voltage, and then, a drain voltage pulse signal DP is switched from an enable voltage to a standby voltage. In contrast, in an erase mode EM, the drain voltage pulse signal DP is switched from the enable voltage to the standby voltage, and then, the gate voltage pulse signal GP is switched from the enable voltage to the standby voltage. The write mode WM, the erase mode EM and the read mode RM are described with reference to FIG. 5 and thus their detailed description will not be repeated here.

However, unlike in the method of FIG. 5, referring to FIG. 6, in the write mode WM, the drain voltage pulse signal DP is switched from the standby voltage to the enable voltage at the same time that the gate voltage pulse signal GP is switched from the standby voltage to the enable voltage. Also, in the erase mode EM, the drain voltage pulse signal DP is switched from the standby voltage to the enable voltage at the same time that the gate voltage pulse signal GP is switched from the standby voltage to the enable voltage.

In the method of FIG. 6, the write mode WM, the read mode RM, the erase mode EM, and the read mode RM are sequentially performed, unlike in the method of FIG. 5.

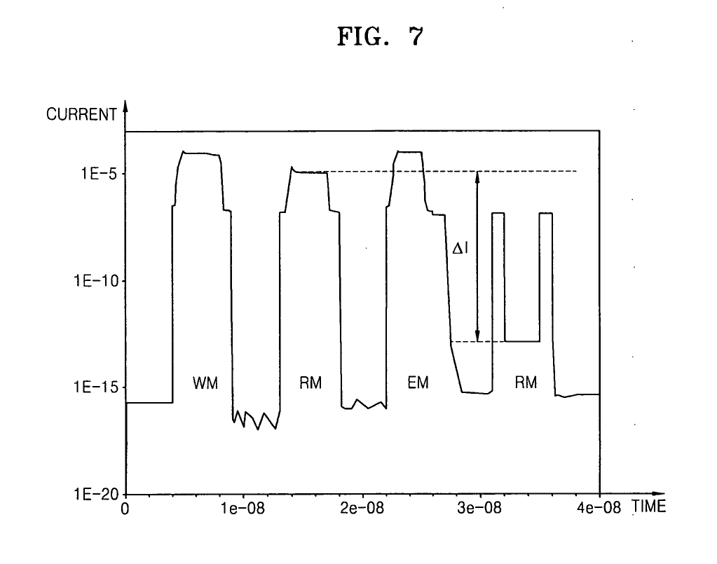

FIG. 7 is a graph illustrating the amount of current that flows between the source region 130 and the drain region 150 when voltage pulse signals are supplied in the operation modes of FIG. 6. Referring to FIG. 7, the amount of current measured in the read mode RM after the write mode WM, may be greater than the amount of current measured in the read mode RM after the erase mode EM, meaning that carriers may be removed from a body region of a memory cell in the erase mode EM. In other words, in the read mode RM after the write mode WM, a large amount of carriers are stored in the body region 170 in the write mode WM and thus a large amount of current flows between the source region 140 and the drain region 150 in the read mode RM. However, in the read mode RM after the erase mode EM, the carriers are removed from the body region 170 in the erase mode EM and thus a small amount of current flows between the source region 140 and the drain region 150 in the read mode RM. Therefore, the data of the memory cell of 1-T DRAM may be detected in the read mode RM according to the amount of current measured in the read mode RM.

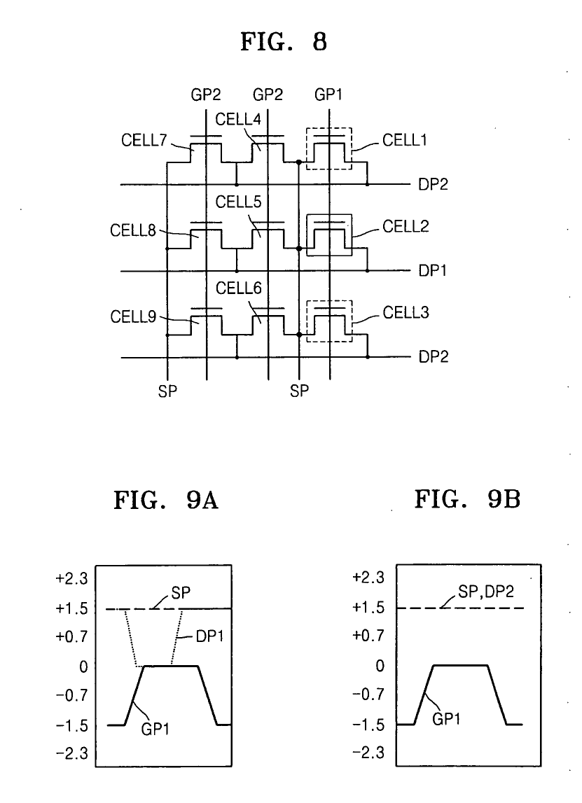

FIG. 8 is a circuit diagram of a semiconductor device including a memory cell of 1T-DRAM that operates according to an example embodiment of a method of operating a semiconductor device. FIG. 8 illustrates first through ninth memory cells CELL1 to CELL9. Referring to FIG. 8, first gate voltage pulse signal GP1 is supplied to the memory cells CELL1 to CELL3 via word lines and second gate voltage pulse signal GP2 is supplied to the memory cells CELL4 to CELL9 via word lines. First and second drain voltage pulse signals DP1 and DP2 and a source voltage signal SP are respectively applied to the corresponding memory cell of the first through ninth memory cells CELL1 to CELL9 via bit lines and source lines.

Referring to FIG. 8, data may be erased from (or written to) the second memory cell CELL2 but may also be erased from (or written to) the other memory cells CELL1 and CELL 3 to CELL9. In FIG. 8, the first gate voltage pulse signal supplied via the word line connected to the second memory cell CELL2 from which data is to be erased (or to which data is to be written) is referred to as ‘GP1’, and the second gate voltage pulse signal supplied via the other word lines is referred to as ‘GP2’. Also, the first drain voltage pulse signal supplied via the bit line connected to the second memory cell CELL2 is referred to as ‘DP1’ and the second drain voltage pulse signal supplied via the other bit lines is referred to as ‘DP2’.

FIGS. 9A and 9B illustrate voltage pulse signals that may be supplied to the semiconductor device of FIG. 8 in an erase mode. FIG. 9A illustrates voltage pulse signals supplied to the second memory device CELL2 of FIG. 8 from which data is to be erased. In order to erase the data from the second memory device CELL2, the first gate voltage pulse signal GP1 is switched from an enable voltage to a standby voltage after the first drain voltage pulse signal DP1 is switched from an enable voltage to a standby voltage.

FIG. 9B illustrates voltage pulse signals supplied to the first and third memory cells CELL1 and CELL3 of FIG. 8 that are connected to the same word line connected to the second memory cell CELL2 of FIG. 8. The second drain voltage pulse signal DP2 may be supplied to the first and third memory cell CELL1 and CELL3. Also, a signal having the same voltage as the first gate voltage pulse signal GP1 supplied to the second memory cell CELL2, may be supplied to the first and third memory cells CELL1 and CELL3. Referring to FIG. 9B, since the source voltage signal SP and the second drain voltage pulse signal DP2 may be a same voltage, the current does not flows between the source region 140 and the drain region 150 irrespective of the first gate voltage pulse signal GP1. Therefore, the carriers are not removed from the body region 170 of the first and third memory cells CELL1 and CELL3.

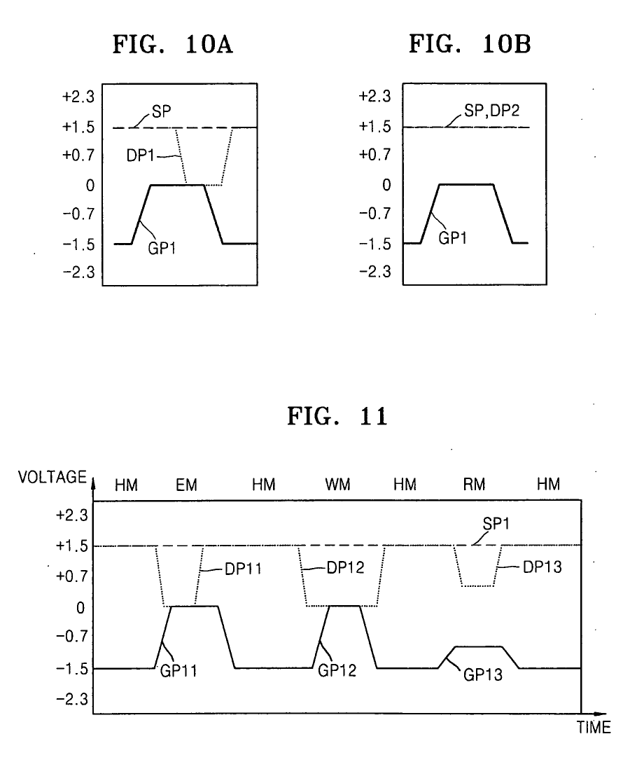

FIGS. 10A and 10B illustrate voltage pulse signals that may be supplied to the semiconductor device of FIG. 8 in a write mode. FIG. 10A illustrates voltage pulse signals supplied to the second memory cell CELL2 to which data is to be written. In order to write the data to the second memory cell CELL2, the first drain voltage pulse signal DP1 is switched from an enable voltage to a standby voltage after the first gate voltage pulse signal GP1 is switched from an enable voltage state to a standby voltage. The write mode is described with reference to FIG. 5 and thus their detailed description will not be repeated here.

FIG. 10B illustrates voltage pulse signals supplied to the first and third memory cells CELL1 and CELL3 connected to the same word line connected to the second memory cell CELL2 of FIG. 10A. The second drain voltage pulse signal DP2 may be supplied to the first and third memory cells CELL1 and CELL3. Also, a signal having the same voltage as the second gate voltage pulse signal GP1 supplied to the second memory cell CELL2 may be supplied to the first and third memory cells CELL1 and CELL3. Referring to FIG. 10B, since the source voltage signal SP and the second drain voltage pulse signal DP2 may be a same voltage, the current does not flows between the source region 140 and the drain region 150 irrespective of the first gate voltage pulse signal GP1. Therefore, the amounts of the carriers in the body region 170 of the first and third memory cells CELL1 and CELL3 are not changed though the second gate voltage pulse signal GP1 is supplied to the first and third memory cells CELL1 and CELL3.

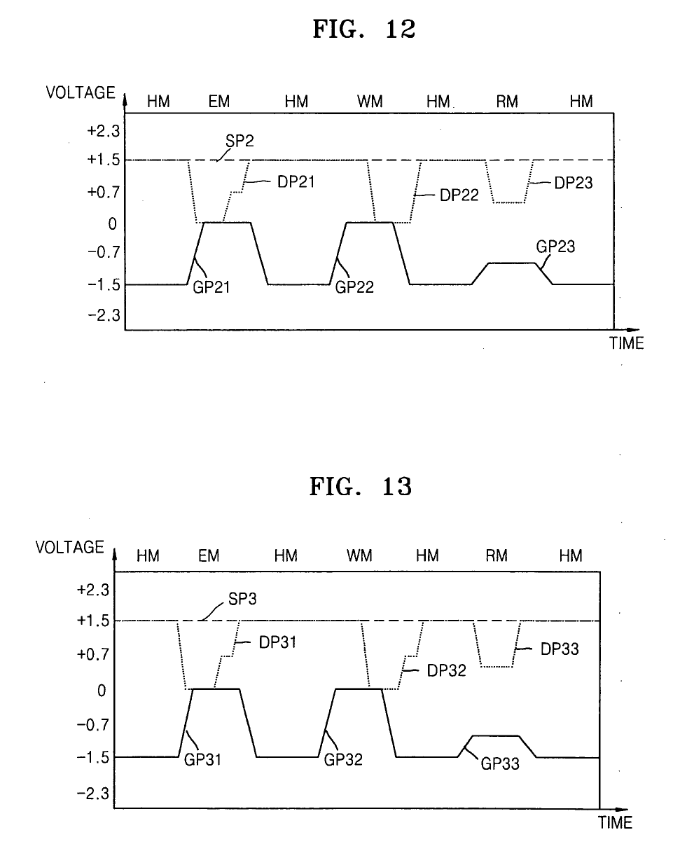

FIGS. 11 to 14 illustrate various voltage pulse signals supplied in operation modes in an example embodiment of a method of operating a semiconductor device. Each pulse is labeled by the pulses voltage type, for Example GP for gate pulse, DP for drain pulse and SP for source pulse. Each pulse label also has subscripts that are sequentially ordered, for example the gate pulses and the drain pulses shown in FIG. 11 include 11, 12 and 13. Therefore, FIG. 11 includes GP11-GP13 with GP11 being first and GP 13 being last. FIGS. 12-14 include similarly labeled pulses which may or may not be described in detail. Referring to FIG. 11, unlike as illustrated in FIG. 5, in a write mode WM, a drain voltage pulse signal DP12 is switched from a standby voltage to an enable voltage before a gate voltage pulse signal GP12 is switched from a standby voltage to an enable voltage.

Referring to FIG. 12, unlike as illustrated in FIG. 5, in an erase mode EM, the drain voltage pulse signal DP21 may have a middle voltage between the standby voltage and the enable voltage for a length of time while a drain voltage pulse signal DP21 is switched from the enable voltage to the standby voltage. For example, the drain voltage pulse signal DP21 has a voltage for the length of time while it is switched from the enable voltage to the standby voltage.

Referring to FIG. 13, unlike as illustrated in FIG. 12, in a write mode WM, the drain voltage pulse signal DP32 may have a middle voltage between the standby voltage and the enable for a length of time while a drain voltage pulse signal DP32 is switched from the enable voltage to the standby voltage. In an erase mode EM, the voltages of a gate voltage pulse signal GP31 and a drain voltage pulse signal DP31 are as illustrated in FIG. 12.

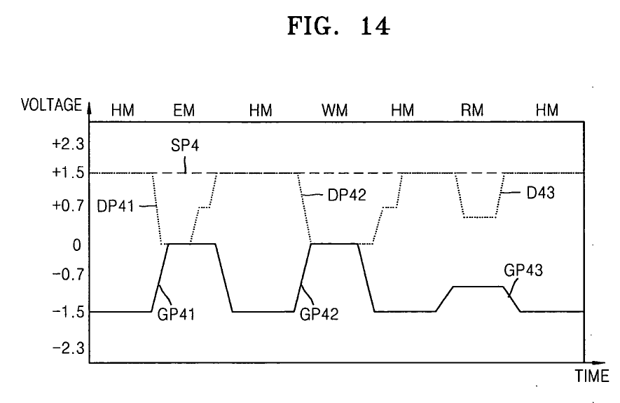

Referring to FIG. 14, a drain voltage pulse signal DP42 has a wider pulse width than the drain voltage pulse signal D32 in FIG. 13. That is, the drain voltage pulse signal DP42 is transitioned from the standby voltage to the enable voltage when the gate voltage pulse signal GP42 is transitioned from the standby voltage to the enable voltage, and the drain voltage pulse signal DP42 is transitioned from the enable voltage to the standby voltage after the gate voltage pulse signal GP42 is transitioned from the enable voltage to the standby voltage. Also the voltage pulse signal DP42 may have a middle voltage between the enable voltage and the standby voltage for a length of time while the voltage pulse signal DP42 is transitioned from the enable voltage to the standby voltage.

In the above example embodiments of a method of operating a semiconductor device, the amplitude of a gate voltage pulse signal supplied in an erase mode may be the same as in a write mode. Also, the amplitude of a drain voltage pulse signal supplied in the erase mode may be the same as in the write mode. In the erase mode and the write mode, the width of the gate voltage pulse signal may be narrower, equal or wider than that of the drain voltage pulse signal. Also, the amplitude of the gate voltage pulse signal may be different from that of a source voltage pulse signal.

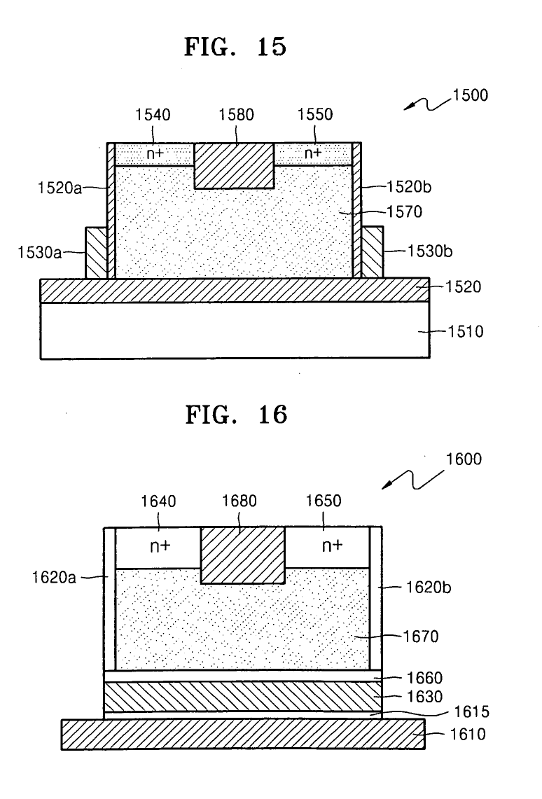

FIG. 15 is a cross-sectional view of an example memory cell 1500 of 1-T DRAM that operates according to example embodiments of a method of operating a semiconductor device. Referring to FIG. 15, the memory cell 1500 of 1-T DRAM may include a semiconductor substrate 1510, an insulating layer 1520, first and second gate patterns 1530a and 1530b, a first impurities-doped region 1540, a second impurities-doped region 1550, and a body region 1570.

The body region 1570 is deposited on the insulating layer 1520. The first and second gate patterns 1530a and 1530b are respectively formed on the insulating layer 1520 along both sides of the body region 1570. The first and second impurities-doped regions 1540 and 1550 are formed on the body region 1570, and may be respectively a drain region and a source region or vice versa.

The first and second gate patterns 1530a and 1530b may be separated by a distance from the first and second impurities-doped regions 1540 and 1550 in the vertical direction, preventing the first and second gate patterns 1530a and 1530b from overlapping with the first and second impurities-doped regions 1540 and 1550.

The first and second gate patterns 1530a and 1530b may extend in a direction perpendicular to a larger surface of the body region 1570. For example, in FIG. 15, the first and second gate patterns 1530a and 1530b may extend in a direction passing through the larger surface of the body region 1570.

The first and second impurities-doped regions 1540 and 1550 may protrude upward from the body region 1570 and may be separated by a distance from each other. An isolating oxide region 1580 may be arranged between the first and second impurities-doped regions 1540 and 1550.

The isolating oxide region 1580 may be formed of a material containing an oxide but may be replaced with an insulating region formed of another insulating material. Also, the oxide regions mentioned here may be replaced with insulating regions formed of another insulating material.

The 1-T DRAM 1500 may further include first and second gate insulating regions 1520a and 1520b. The first gate insulating region 1520a may be located between the first gate pattern 1530a and the body region 1570, and the second gate insulating region 1520b may be located between the second gate pattern 1530b and the body region 1570. The first and second gate insulating regions 1520a and 1520b insulate the first gate pattern 1530a and the second gate insulating region 1520b from the body region 1570.

The 1-T DRAM 1500 may further include a buried oxide (BOX) region (not shown) in the semiconductor substrate 1510. The BOX region may be obtained by forming an oxide region in the semiconductor substrate 1510 formed from a bulk substrate, or an insulating region in a silicon-on-insulator (SOI) substrate may be used as the BOX region.

FIG. 16 illustrates another example 1600 of a 1-T DRAM that operates according to an example embodiment of a method of operating a semiconductor device. Referring to FIG. 16, the 1-T DRAM 1600 may include a semiconductor substrate 1610, a gate pattern 1630, a first impurities-doped region 1640, a second impurities-doped region 1650, an insulating layer 1660 and a body region 1670.

The gate pattern 1630 may be disposed on the semiconductor substrate 1610. The body region 1670 may be disposed on the gate pattern 1630. The first and second impurities-doped regions 1640 and 1650 may be formed on the body region 1670. That is, the gate pattern 1630 may be located below the body region 1670 and the first and second impurities-doped regions 1640 and 1650.

The body region 1670 may be a floating body region separated from the semiconductor substrate 1610. The body region 1670 and the semiconductor substrate 1610 may be formed of the same material.

The 1-T DRAM 1600 may further include a BOX region 1615 formed on the semiconductor substrate 1610. The 1-T DRAM 1600 may further include first and second insulating regions 1620a and 1620b. The first and second insulating regions 1620a and 1620b may be disposed along a side of the body region 1670. The first and second insulating regions 1620a and 1620b may insulate the body region 1670 from the other elements. Also, the first and second insulating regions 1620a and 1620b may be disposed along both sides of the gate pattern 1630 and the body region 1670. The first and second insulating regions 1620a and 1620b may insulate the gate pattern 1630 and the body region 1670 from the other elements.

While the example embodiments have been particularly shown and described, it will be understood by one of ordinary skill in the art that variations in form and detail may be made therein without departing from the spirit and scope of the claims.

What is claimed is:

1. A method of operating a semiconductor device including a plurality of memory cells, each memory cell including a drain region, a source region, a floating body region, and a gate electrode, the method comprising:
switching a gate voltage pulse signal supplied to the gate electrode from a gate enable voltage to a gate standby voltage after a drain voltage pulse signal supplied to the drain region is switched from a drain enable voltage to a drain standby voltage, to change a data state of at least one of memory cells to a first state if in an erase mode; and
switching the drain voltage pulse signal from the drain enable voltage to the drain standby voltage after the gate voltage pulse signal is switched from the gate enable voltage to the gate standby voltage, to change the data state of at least one of memory cells to a second state if in a write mode; wherein
the drain standby voltage is higher than the drain enable voltage, and
the gate enable voltage is higher than the gate standby voltage.

2. The method of claim 1, wherein the erase mode further comprising one of:
switching the gate voltage pulse signal from the enable voltage to the standby voltage after the drain voltage pulse signal is switched from the enable voltage to the standby voltage; and
switching the drain voltage pulse signal from the enable voltage to the standby voltage at the same time that the gate voltage pulse signal is switched from the enable voltage to the standby voltage.

3. The method of claim 1, the erase mode further comprising:
switching the drain voltage pulse signal from the standby voltage to the enable voltage one of before and after the gate voltage pulse signal is switched from the standby voltage to the enable voltage.

4. The method of claim 1, the erase mode further comprising:
switching the drain voltage pulse signal from the standby voltage to the enable voltage at the same time the gate voltage pulse signal is switched from the standby voltage to the enable voltage.

5. The method of claim 1, the write mode further comprising one of:
switching the drain voltage pulse signal from the enable voltage to the standby voltage after the gate voltage pulse signal is switched from the enable voltage to the standby voltage; and
switching the drain voltage pulse signal from the enable voltage to the standby voltage at the same time that the gate voltage pulse signal is switched from the enable voltage to the standby voltage.

6. The method of claim 3 the write mode further comprising:
switching the drain voltage pulse signal from the standby voltage to the enable voltage one of before and after the gate voltage pulse signal is switched from the standby voltage to the enable voltage.

7. The method of claim 3 the write mode further comprising:
switching the drain voltage pulse signal from the standby voltage to the enable voltage at the same time the gate voltage pulse signal is switched from the standby voltage to the enable voltage.

8. The method of claim 4 the write mode further comprising:
switching the drain voltage pulse signal from the standby voltage to the enable voltage one of before and after the gate voltage pulse signal is switched from the standby voltage to the enable voltage.

9. The method of claim 4 the write mode further comprising:
switching the drain voltage pulse signal from the standby voltage to the enable voltage at the same time the gate voltage pulse signal is switched from the standby voltage to the enable voltage.

10. The method of claim 1, further comprising:
maintaining a voltage of the drain voltage pulse signal equal to a voltage between the standby voltage and the enable voltage for a length of time while the drain voltage pulse signal is switched from the enable voltage to the standby voltage, wherein the semiconductor device is in one of the erase mode and the write mode.

11. The method of claim 1, further comprising:
supplying a source voltage signal to the source region, if the semiconductor is in one of the erase made and the write mode, including one of supplying a source voltage pulse signal in the form of a pulse and supplying a constant voltage.

12. The method of claim 1, wherein the standby voltage and the enable voltage of the drain voltage pulse signal are one of equal to and greater than the standby voltage and the enable voltage of the gate voltage pulse signal.

13. The method of claim 1, wherein the semiconductor device includes,
a semiconductor substrate,
a body region on the semiconductor substrate,
first and second gate electrodes on the semiconductor substrate along both sides of the body region, and
first and second impurities-doped regions above the body region.

14. The method of claim 1, wherein the first and second gate electrodes are separated from the first and second impurities-doped regions in a vertical direction, so that the first and second gate patterns do not overlap with the first and second impurities-doped regions.

15. The method of claim 1, wherein the semiconductor device includes
a semiconductor substrate,
a gate pattern on the semiconductor substrate,
a body region on the gate pattern, and
first and second impurities-doped regions above the body region.

16. A method of erasing data from a plurality of memory cells, each memory cell including a drain region, a source region, a floating body region, and a gate electrode, the method comprising:
if in an erase mode
switching a drain voltage pulse signal supplied to the drain region; and
one of switching the gate voltage pulse signal from a gate enable voltage to a gate standby voltage after the drain voltage pulse signal from a drain enable voltage to a drain standby voltage, and switching the gate voltage pulse signal from the gate enable voltage to the gate standby voltage at the same time that the drain voltage pulse signal is switched from the drain enable voltage to the drain standby voltage, wherein the drain standby voltage is higher than the drain enable voltage, and the gate enable voltage is higher than the gate standby voltage.

17. The method of claim 16, further comprising:
If in a write mode, switching the drain voltage pulse signal from the drain standby voltage to the drain enable voltage is performed one of before and after the gate voltage pulse signal supplied to the gate electrode is switched from the gate standby voltage to the gate enable voltage.

18. The method of claim 16, wherein the write mode further comprising:
switching the drain voltage pulse signal from the drain standby voltage to the drain enable voltage is performed at the same time the gate voltage pulse signal supplied to the gate electrode is switched from the gate standby voltage to the gate enable voltage.

19. The method of claim 16, wherein
drain regions of the plurality of the memory cells are connected to a corresponding bit line,
gate electrodes of the plurality of the memory cells are connected to a corresponding word line,
the gate voltage pulse signal is supplied to a selected word line connected to a memory cell from which data is to be erased among the plurality of the memory cells,
the drain voltage pulse signal is supplied to a selected bit line connected to the memory cell from which data is to be erased, and
a drain voltage signal having a voltage is supplied to the other bit lines except for the selected bit line.

20. The method of claim 19, wherein the voltage of the drain voltage signal supplied to the other bit lines is higher than the enable voltage of the gate voltage pulse signal.

21. A method of writing data to a plurality of memory cells, each memory cell including a drain region, a source region, a floating body region, and a gate electrode, the method of writing data comprising:
switching a drain voltage pulse signal supplied to the drain region from a standby voltage to an enable voltage before, after or at the same time that a gate voltage pulse signal supplied to the gate electrode is switched from a standby voltage to an enable voltage; and
switching the drain voltage pulse signal from the enable voltage to the standby voltage after the gate voltage pulse signal is switched from the enable voltage to the standby voltage, or the gate voltage pulse signal is switched from the enable voltage to the standby voltage at the same time that the drain voltage pulse signal is switched from the enable voltage to the standby voltage, wherein the standby voltage of the drain voltage pulse signal is higher than the enable voltage of the drain voltage pulse signal, and an enable voltage of the gate voltage pulse signal is higher than a standby voltage of the gate voltage pulse signal.

22. The method of claim 15, wherein
drains of the plurality of the semiconductor devices are connected to a plurality of bit lines,
gates of the plurality of the semiconductor devices are connected to a plurality of word lines,
the gate voltage pulse signal is supplied to a selection word line connected to a semiconductor device to which data is to be written from among the plurality of the semiconductor devices,
the drain voltage pulse signal is supplied to a selection bit line connected to the semiconductor device to which data is to be written, and
a drain voltage signal having a voltage is supplied to the other bit lines except for the selection bit line.
